(19) United States
(12) Patent Application Publication
(10) Pub. No.: US 2011/0285013 A1
(43) Pub. Date: Nov. 24, 2011

(54) Controlling Solder Bump Profiles by Increasing Heights of Solder Resists

(75) Inventors: Yao-Chun Chuang, Taipei City (TW); Chen-Cheng Kuo, Chu-Pei City (TW); Chen-Shien Chen, Zhubei City (TW)

(73) Assignee: Taiwan Semiconductor Manufacturing Company, Ltd., Hsin-Chu (TW)

(21) Appl. No.: 12/784,335

(22) Filed: May 20, 2010

(51) Int. Cl. H01L 23/488

(52) U.S. Cl. 257/737; 257/778; 257/779; 257/E23.023

(57) ABSTRACT

A device includes a first work piece bonded to a second work piece. The first work piece includes a solder resist at a surface of the first work piece, wherein the solder resist includes a solder resist opening, and a bond pad in the solder resist opening. The second work piece includes a non-reflowable metal bump at a surface of the second work piece. A solder bump bonds the non-reflowable metal bump to the bond pad, with at least a portion of the solder bump located in the solder resist opening and adjoining the non-reflowable metal bump and the bond pad. A thickness of the solder resist is greater than about 50 percent a height of the solder bump, wherein the height equals a distance between the non-reflowable metal bump and the bond pad.

### TECHNICAL FIELD

This disclosure relates generally to integrated circuits, and more particularly to flip-chip bond structures and methods for forming the same.

### BACKGROUND

In the manufacturing of wafers, integrated circuit devices such as transistors are first formed at the surfaces of semiconductor substrates in the semiconductor wafers. Interconnect structures are then formed over the integrated circuit devices. Bumps are formed on the surfaces of the semiconductor wafers, and are electrically coupled to integrated circuit devices. The semiconductor wafers are sawed into semiconductor chips, also commonly known as dies.

In the packaging of the semiconductor chips, the semiconductor chips are often bonded with package substrates using flip-chip bonding. Solders are used to join the bumps in the semiconductor chips to the bond pads in the package substrates. When two semiconductor chips (or one semiconductor chip and a package substrate) are bonded, solder may be pre-formed on one, or both, of the bumps/pads of the semiconductor chips. A re-flow is then performed so that the solder joins the semiconductor chips.

FIG. 1 illustrates an exemplary bond structure for bonding chip 202 and chip 204. Solder 210 is used to bond metal bump 212 in chip 202 to bond pad 214. If standoff distance D is defined as being the distance between solder resist 206 in chip 204 and dielectric layer 208 in chip 202, the due to the warpage of chips 202 and 204, standoff distance D may change from bond structure to bond structure. For example, after bonding, the standoff distances D of bond structures close to the edges of chips 202 and 204 may be greater than that of bond structures close to the centers of chips 202 and 204. As a result, the solder bump profile is difficult to control. For example, in FIG. 1, solder 210 may be squeezed aside by copper bump 212, which often occurs for bond structures close to the edges of the chips, while for locations close to the centers of the chips, such a profile may not appear. The non-uniformity in the profile of solder bumps may cause bump crack, and need to be resolved.

### SUMMARY

In accordance with one aspect of the embodiment, a device includes a first work piece bonded to a second work piece. The first work piece includes a solder resist at a surface of the first work piece, wherein the solder resist includes a solder resist opening, and a bond pad in the solder resist opening. The second work piece includes a non-reflowable metal bump at a surface of the second work piece. A solder bump bonds the non-reflowable metal bump to the bond pad, with at least a portion of the solder bump located in the solder resist opening and adjoining the non-reflowable metal bump and the bond pad. A thickness of the solder resist is greater than about 50 percent a height of the solder bump, wherein the height equals a distance between the non-reflowable metal bump and the bond pad.

Other embodiments are also disclosed.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1 illustrates a conventional bond structure, with solder in the bond structure being squeezed aside;

FIG. 2 illustrates a cross-sectional view of a first work piece comprising a non-reflowable metal bump;

FIGS. 3A and 3B illustrate cross-sectional views of a second work piece comprising a solder with at least a portion in a solder resist opening; and

FIGS. 4 through 11 are cross-sectional views of bond structures in accordance with various embodiments.

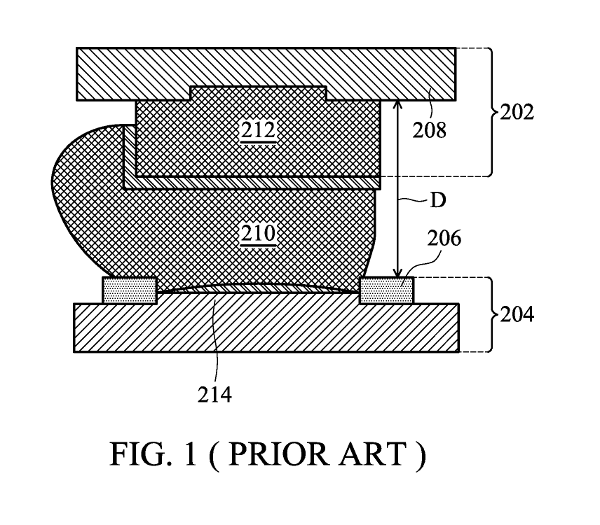

### DETAILED DESCRIPTION OF ILLUSTRATIVE EMBODIMENTS

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

A novel bond structure is provided in accordance with an embodiment. The variations of the embodiment are discussed. Throughout the various views and illustrative embodiments, like reference numbers are used to designate like elements.

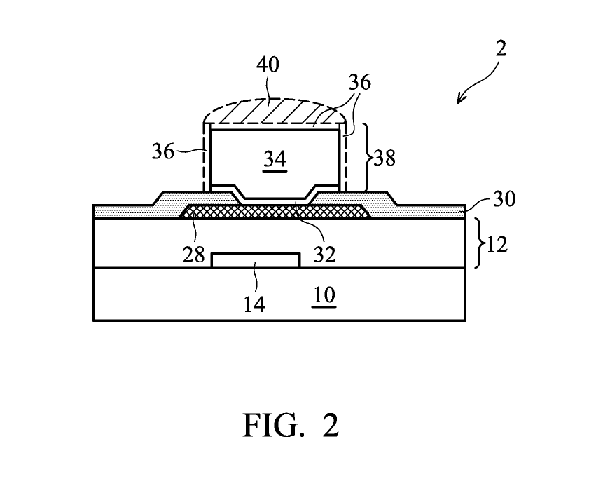

Referring to FIG. 2, work piece 2, which includes substrate 10, is provided. Work piece 2 may be a device die that includes active devices such as transistors therein, although it may also be a package substrate or an interposer that does not have active devices therein. In an embodiment wherein work piece 2 is a device die, substrate 10 may be a semiconductor substrate such as a silicon substrate, although it may include other semiconductor materials. Semiconductor devices 14 such as transistors may be formed at a surface of substrate 10. Interconnect structure 12, which includes metal lines and vias (not shown) formed therein and connected to semiconductor devices 14, is formed over substrate 10. The metal lines and vias may be formed of copper or copper alloys, and may be formed using the well-known damascene processes. Interconnect structure 12 may include commonly known inter-layer dielectrics (ILDs) and inter-metal dielectrics (IMDs).

Metal pad 28 is formed over interconnect structure 12. Metal pad 28 may comprise aluminum (Al), copper (Cu), silver (Ag), gold (Au), nickel (Ni), tungsten (W), alloys thereof, and/or multi-layers thereof. Metal pad 28 may be electrically coupled to semiconductor devices 14, for example, through the underlying interconnection structure 12. Passivation layer 30 may be formed to cover edge portions of metal pad 28. In an exemplary embodiment, passivation layer 30 is formed of polyimide or other known dielectric materials such as silicon nitride, silicon oxide, and the like.

Under bump metallurgy (UBM) 32 is formed on, and electrically connected to, metal pad 28. UBM 32 may include a copper layer and a titanium layer (not shown). Copper bump 34 is formed on UBM 32. In an embodiment, copper bump 34 is formed by plating. An exemplary plating process includes forming a blanket UBM layer (not shown, wherein UBM 32 is a part of the UBM layer), forming a mask (not shown) on the UBM layer, patterning the mask to form an opening, plating copper bump 34 in the opening, and removing the mask and the portion of the UBM layer previously covered by the mask. Copper bump 34 may be formed of pure copper or copper alloys.

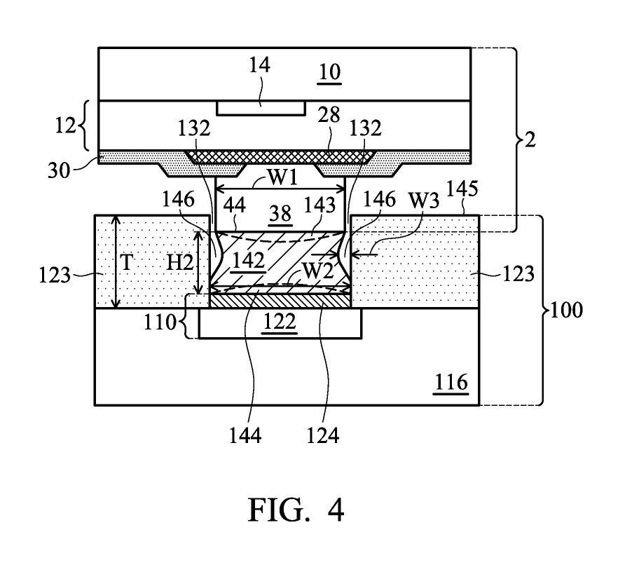

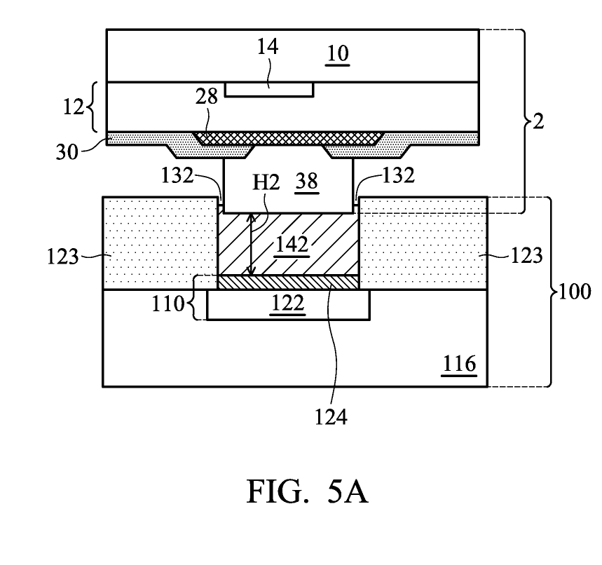

Metal finish 36 may be formed on copper bump 34, for example, by plating. Metal finish 36 may comprise different materials and layers, and may be used to prevent the oxidation and the diffusion of copper bump 34 to/from solder 142 (not shown in FIG. 2, please refer to FIG. 4). In an embodiment, metal finish 36 is formed of nickel, although other metals may be added. Alternatively, metal finish 36 may be formed of electroless nickel electroless palladium immersion gold (ENEPIG), which includes a nickel layer, and a palladium layer on the nickel layer, with both formed using electroless plating. The ENEPIG further includes a gold layer on the palladium layer, wherein the gold layer may be formed using immersion plating. In other embodiments, metal finish 36 may be formed of other known finish materials and methods, including, but not limited to, electroless nickel immersion gold (ENIG), direct immersion gold (DIG), or the like. Metal finish 36 may be limited in the region directly over copper bump 34, and is not formed on sidewalls of copper bump 34. Alternatively, metal finish 36 is also formed on the sidewalls of copper bump 34, as illustrated using dotted lines. In subsequent discussion, UBM 32, copper bump 34, and metal finish 36 in combination are referred to as non-reflowable metal bump 38 since they do not melt in the subsequent reflow for forming solder 142 (please refer to FIG. 4). Solder cap 40 may optionally be formed on non-reflowable metal bump 38, and may comprise a lead-free solder material containing, for example, SnAg, SnAgCu, and the like, although solder cap 40 may also be formed of an eutectic solder material containing, for example, lead (Pb) and tin (Sn).

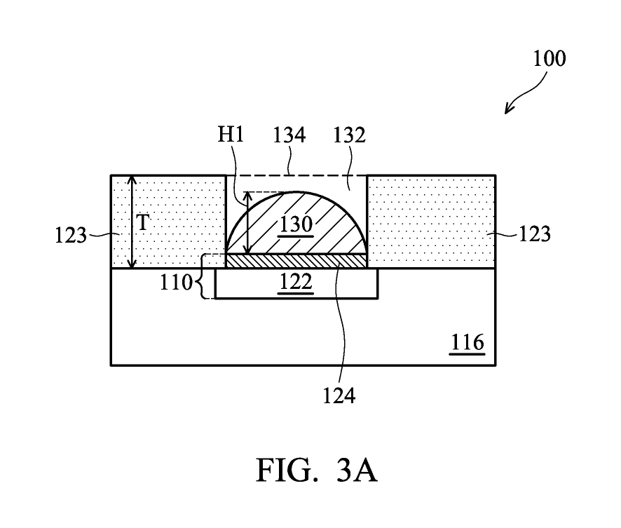

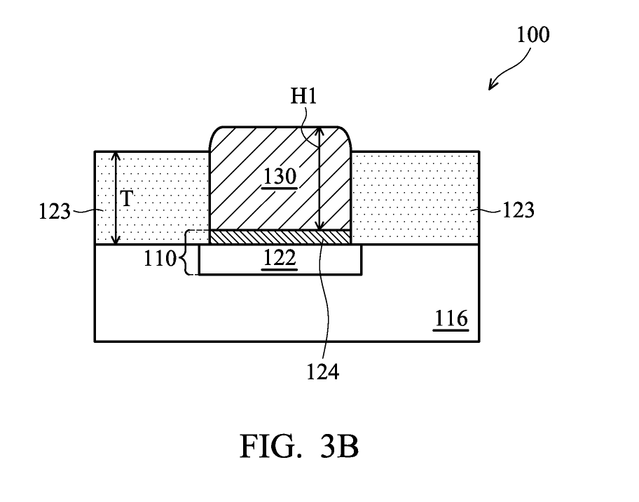

FIGS. 3A and 3B illustrates work piece 100, which may be a package substrate, although it may also be a device die, an interposer, or the like. Work piece 100 may include bond pad 110. Electrical connections (for example, redistribution lines, not shown) may be formed in dielectric layer(s) 116 in work piece 100, and are electrically coupled to bond pad 110.

Bond pad 110 comprises metal pad 122, which may be formed of copper (for example, pure or substantially pure copper), aluminum, silver, and alloys thereof. In an embodiment for forming metal pad 110, metal pad 122 is formed first. Solder resist 123 is then formed and patterned to form solder resist opening 132 (FIG. 3A), with metal pad 122 being exposed through solder resist opening 132. Solder resist 123 may be formed of a polymer, which may also be a photo resist. The thickness T of solder resist 123 may be greater than about 25 μm, or greater than about 50 μm, and may also be between about 25 μm and about 100 μm. Conductive barrier layer 124 may then be formed over metal pad 122 as a part of bond pad 110, for example, using electroless or electro plating. Conductive barrier layer 124 may be formed of nickel, although other metals/layers such as palladium may be added.

Solder ball 130 is formed on barrier layer 124, wherein a solder ball is picked up and placed into solder resist opening 132. The solder ball is then reflowed to form solder ball 130. Solder ball 130 may be formed of essentially the same material as, or selected from the same group as, solder cap 40 as in FIG. 2, although the materials of solder cap 40 and solder ball 130 may also be different. In an embodiment as shown in FIG. 3A, height H1 of solder ball 130 is lower than thickness T of solder resist 123. Accordingly, solder ball 130 is embedded in solder resist opening 132 that is defined by solder resist 123. Dotted line 134 illustrates a boundary of solder resist opening 132. In alternative embodiments, height H1 of solder ball 130 may be equal to or slightly greater than thickness T. The volume of solder ball 130 may be equal to or less than the volume of solder resist opening 132.

In alternative embodiments as shown in FIG. 3B, height H1 of solder ball 130 is greater than thickness T of solder resist 123. Accordingly, solder ball 130 protrudes beyond the top surface of solder resist 123. To form the solder ball 130 as shown in FIG. 3B, a big solder ball may be placed with a portion in solder resist opening 132. A flux may then be applied on the solder ball, followed by a reflow step to melt the big solder ball, with the big solder ball being pressed during the reflow using a hard flat surface until the big solder ball is cooled and solidified to form solder ball 130.

Work piece 2 and work piece 100 may be bonded through flip-chip bonding, as shown in FIG. 4. A reflow process is performed to melt solder ball 130 and solder cap 40 (FIG. 2), if any, so that solder bump 142 is formed to bond non-reflowable metal bump 38 with bond pad 110. Due to the inter-diffusion between non-reflowable metal bump 38 and solder bump 142, inter-metallic compound (IMC) 143 may be formed. Similarly, IMC 144 also forms at the interface between solder bump 142 and bond pad 110. In subsequent discussion, IMCs 143 and 144 are also construed as being a part of solder bump 142, and are not illustrated in subsequent drawings, although they may exist in each of the illustrated embodiments.

In FIG. 4, the total volume of solder bump 142, which is the sum of the volume of solder ball 130 as shown in FIG. 3A and the volume of solder cap 40 as shown in FIG. 2, if any, is less than the volume (the capacity) of solder resist opening 132. Accordingly, non-reflowable metal bump 38 may extend into solder resist opening 132. The bottom surface 44 of non-reflowable metal bump 38 is also below the top surface 145 of solder resist 123. The height H2 of solder bump 142 is thus less than, or equal to, thickness T of solder resist 123. Throughout the description, height H2 is equal to the distance between non-reflowable metal bump 38 and bond pad 110.

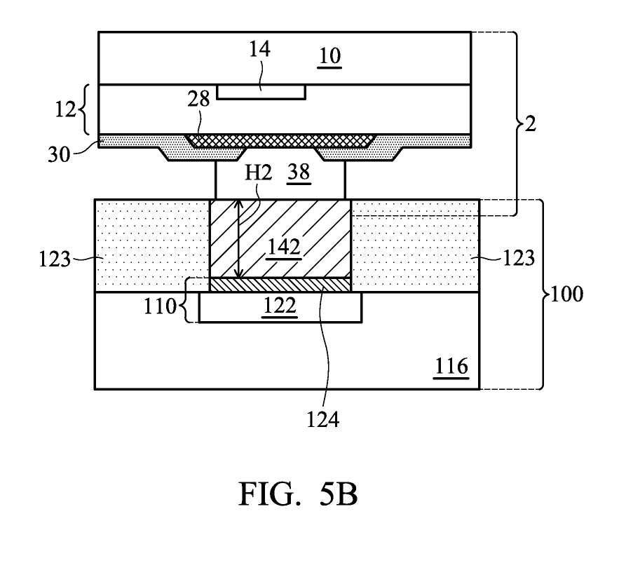

A horizontal dimension (which may be a length or a width) W1 of non-reflowable metal bump 38 may be less than the respective horizontal dimension W2 of solder resist opening 132. In an exemplary embodiment, horizontal dimension W1 is between 0.7 times horizontal dimension W2 and about 1 time W2. Accordingly, gap(s) 146 may exist in solder resist opening 132, and horizontally spaces solder bump 142 from the respective edge of solder resist 123. Width W3 of gap 146 may be less than about 30 μm, or less than about 20 μm, for example. FIG. 5A illustrates an embodiment similar to the embodiment shown in FIG. 4, except no gap exists in solder resist opening 132 and spaces solder bump 142 apart from the respective edge of solder resist 123. In FIG. 5B, a surface of non-reflowable metal bump 38 is level with, or substantially level with, the top surface of solder resist 123. Further, the total volume of solder bump 142 may be substantially equal to the volume (the capacity) of solder resist opening 132.

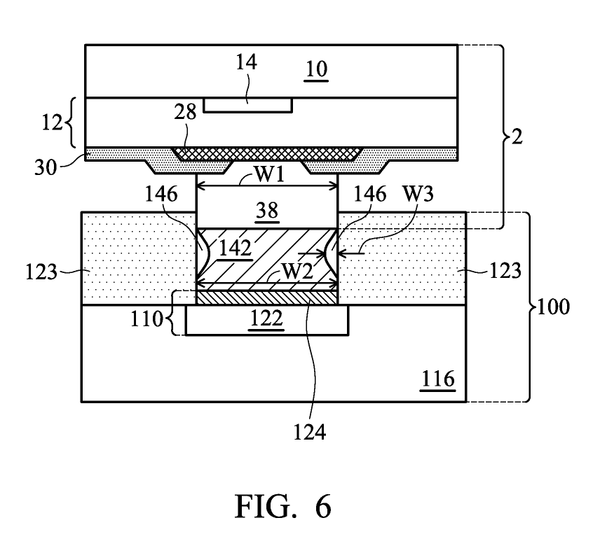

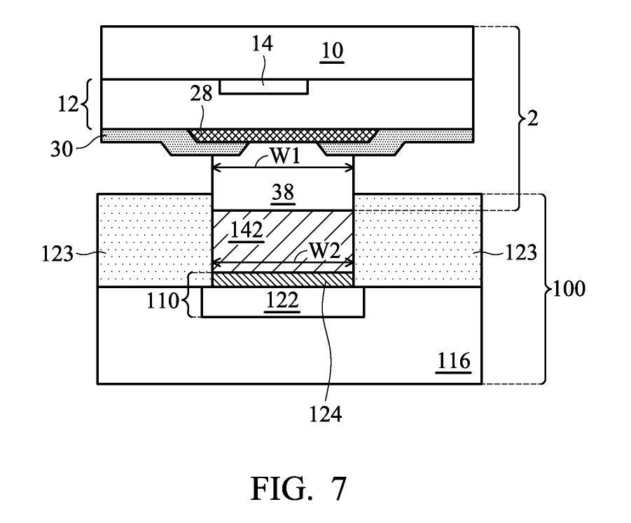

FIGS. 6 and 7 illustrate variations of embodiments. The embodiment shown in FIG. 6 is similar to the embodiment shown in FIG. 4, except that horizontal dimension W1 of non-reflowable metal bump 38 is substantially equal to the respective horizontal width W2 of solder resist opening 132. The embodiment shown in FIG. 7 is similar to the embodiment shown in FIG. 5A. Again, horizontal dimension W1 of non-reflowable metal bump 38 is substantially equal to the respective horizontal width W2 of solder resist opening 132.

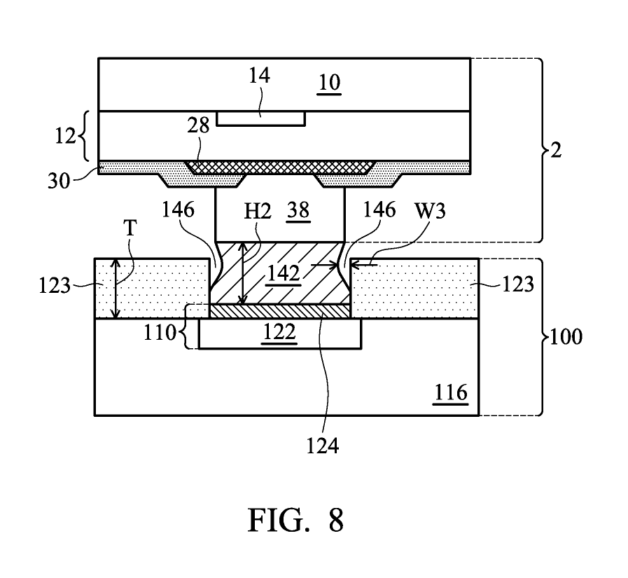

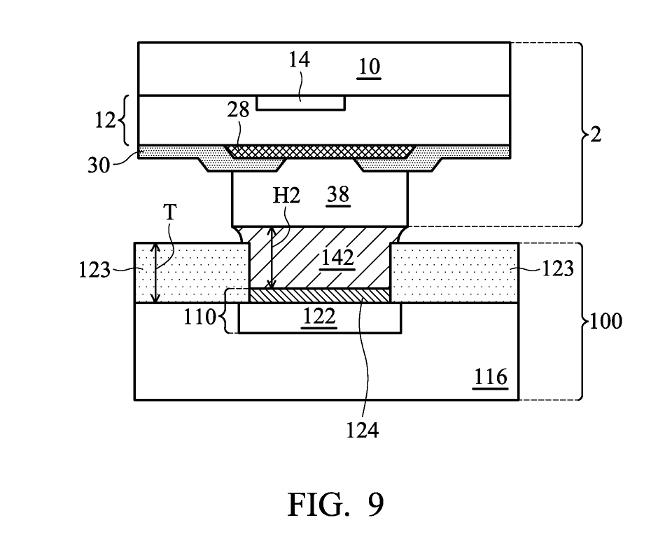

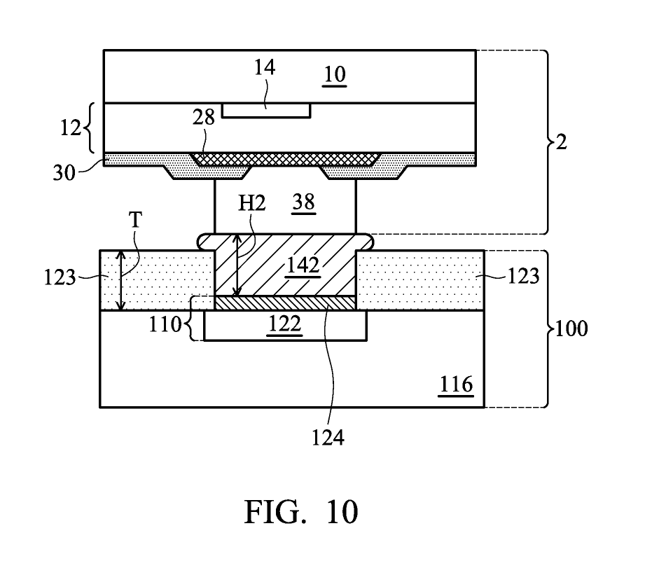

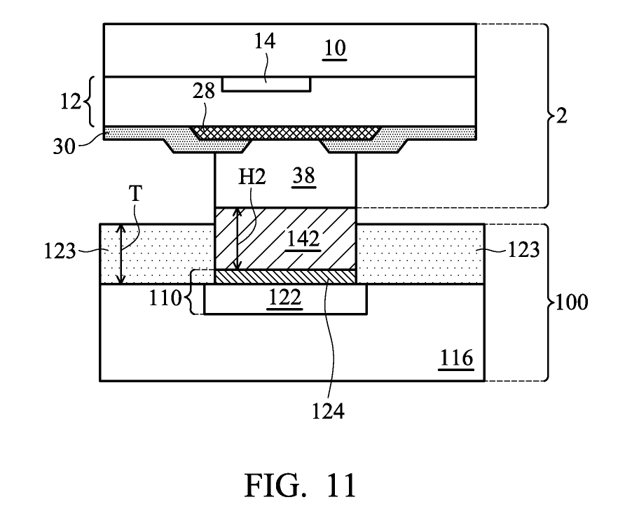

FIGS. 8 through 11 illustrate yet other variations of embodiments. In these embodiments, thickness T of solder resist 123 is less than height H2 of solder bump 142. However, thickness T of solder resist 123 is increased over the thicknesses of solder resists in conventional bonding structures, wherein thicknesses of conventional solder resists were only about 20 μm or less. Further, thickness T is increased to about 50 percent of height H2 or greater. Again, in FIG. 8, gap(s) 146 exist to horizontally spaces solder bump 142 apart from the respective edge of solder resist 123, with width W3 being less than about 30 μm, or less than about 20 μm. In FIG. 9, solder resist opening 132 (not shown in FIG. 9, please refer to FIG. 3A) is fully filled by solder bump 142. In FIG. 10, solder bump 142 may be slightly squeezed sideways to beyond the sidewalls of non-reflowable metal bump 38. FIG. 11 illustrates an embodiment wherein the sidewalls of solder bump 142 are substantially vertically aligned to the respective sidewalls of non-reflowable metal bump 38.

In the embodiments, by increasing the height of solder resist 123, the volume of solder resist opening 132 (FIG. 3A) is increased. Accordingly, when the bonding between two work pieces is performed, the reflowed solder is confined by solder resist 123 in horizontal directions, and hence will provide high vertical forces to the work pieces. The confinement to the solder may result in more uniform solder profiles and less solder cracking. Further, the confinement helps reduce the die warpage.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A device comprising:
a first work piece comprising:
a solder resist on the first work piece, wherein the solder resist comprises a solder resist opening; and
a bond pad on the first work piece and within the solder resist opening;
a second work piece comprising a non-reflowable metal bump on the second work piece; and
a solder bump bonding the non-reflowable metal bump to the bond pad, with at least a portion of the solder bump in the solder resist opening and adjoining the non-reflowable metal bump and the bond pad, wherein the solder bump has a height equal to a distance between the non-reflowable metal bump and the bond pad, and wherein the solder resist has a thickness greater than about 50 percent of the height of the solder bump.

2. The device of claim 1, wherein the thickness of the solder resist is not less than the height of the solder bump.

3. The device of claim 1, wherein the thickness of the solder resist is less than the height of the solder bump.

4. The device of claim 1, wherein the non-reflowable metal bump extends into the solder resist opening.

5. The device of claim 1, wherein a surface of the non-reflowable metal bump is substantially level with a surface of the solder resist.

6. The device of claim 1, wherein the solder resist comprises a polymer.

7. The device of claim 1, wherein the solder resist comprises a photo resist.

8. The device of claim 1, wherein a horizontal dimension of the non-reflowable metal bump is not greater than a respective horizontal dimension of the solder resist opening, and is greater than about 70 percent the respective horizontal dimension of the solder resist opening.

9. The device of claim 1, wherein the first work piece is a package substrate, and the second work piece is a device die.

10. A device comprising:
a first work piece comprising:
a bond pad;
a solder resist on the first work piece, wherein the solder resist comprises a solder resist opening having a first volume;
a bond pad on the first work piece and within the solder resist opening; and
a solder layer on the bond pad and within the solder resist opening, wherein the solder layer has a second volume not greater than the first volume of the solder resist opening.

11. The device of claim 10, wherein a height of the solder layer is substantially equal to or less than a thickness of the solder resist.

12. The device of claim 10, wherein a height of the solder layer is substantially greater than a thickness of the solder resist.

13. The device of claim 10, wherein the solder resist comprises a polymer.

14. The device of claim 10 further comprising a second work piece comprising a non-reflowable metal bump at a surface of the second work piece, wherein the non-reflowable metal bump is bonded to the solder layer.

15. The device of claim 14, wherein the non-reflowable metal bump extends into the solder resist opening.

16. The device of claim 14, wherein a distance between the non-reflowable metal bump and the bond pad is equal to or less than a thickness of the solder resist.

17. The device of claim 14, wherein a distance between the non-reflowable metal bump and the bond pad is greater than a thickness of the solder resist.

18. The device of claim 14, wherein the first work piece is a package substrate, and the second work piece is a device die.
